(19) United States
(12) Patent Application Publication
(10) Pub. No.: US 2024/0381672 A1
(43) Pub. Date: Nov. 14, 2024

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventor: Sung Wook JUNG, Gyeonggi-do (KR)

(21) Appl. No.: 18/452,567

(22) Filed: Aug. 21, 2023

(30) Foreign Application Priority Data
May 11, 2023 (KR) 10-2023-0061300

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2924/1431; H01L 2924/14511

(57) ABSTRACT

A semiconductor device may include: a first semiconductor structure including a stack including an inverted step structure, a source structure located below the stack, a bit line located above the stack, and channel structures extending through the stack; a second semiconductor structure bonded to the first semiconductor structure and including pass transistors located to face the inverted step structure and a first peripheral circuit located to face the source structure; and a third semiconductor structure bonded to the first semiconductor structure and including a page buffer located to face the bit line and a second peripheral circuit located to face the inverted step structure.

### CROSS-REFERENCE TO RELATED APPLICATION

This application claims priority under 35 U.S.C. § 119 to Korean Patent Application No. 10-2023-0061300 filed on May 11, 2023, which is incorporated herein by reference in its entirety.

### BACKGROUND

### 1. Technical Field

Embodiments of the present disclosure relate to an electronic device and a manufacturing method of the electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been considered. Furthermore, in order to improve the operational reliability of such a three-dimensional semiconductor device, various structures and manufacturing methods have been developed.

### SUMMARY

In one embodiment, a semiconductor device may include: a first semiconductor structure including a stack including an inverted step structure, a source structure located below the stack, a bit line located above the stack, and channel structures extending through the stack; a second semiconductor structure bonded to the first semiconductor structure and the second semiconductor structure including a) pass transistors located to face the inverted step structure and b) a first peripheral circuit located to face the source structure; and a third semiconductor structure bonded to the first semiconductor structure and the third semiconductor structure including a) a page buffer located to face the bit line and b) a second peripheral circuit located to face the inverted step structure.

In another embodiment, a manufacturing method of a semiconductor device may include: forming a first semiconductor structure including a stack including a step structure, a source structure located above the stack, and channel structures extending through the stack; forming a second semiconductor structure including pass transistors and a first peripheral circuit; bonding the first semiconductor structure and the second semiconductor structure to each other; forming a third semiconductor structure including a page buffer and a second peripheral circuit; and bonding the first semiconductor structure and the third semiconductor structure to each other.

### BRIEF DESCRIPTION OF THE DRAWINGS

FIGS. 1A and 1B are diagrams for describing a semiconductor device in accordance with one embodiment.

FIG. 2 is a diagram for describing a semiconductor device in accordance with another embodiment.

FIG. 3 is a diagram for describing a manufacturing method of a semiconductor device in accordance with still other embodiments.

FIGS. 4A to 4D are diagrams for describing a manufacturing method of a semiconductor device in accordance with further embodiments.

### DETAILED DESCRIPTION

Various embodiments are directed to a semiconductor device having a stable structure and improved characteristics and a manufacturing method of the semiconductor device.

According to the present technology, it is possible to provide a semiconductor device having a stable structure and improved reliability.

Hereafter, embodiments in accordance with the technical spirit of the present disclosure will be described with reference to the accompanying drawings.

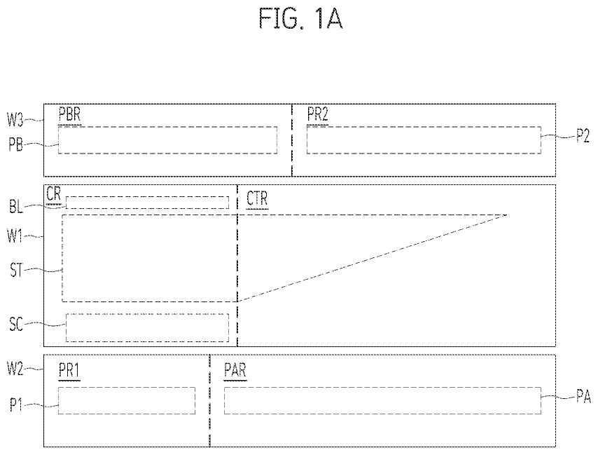

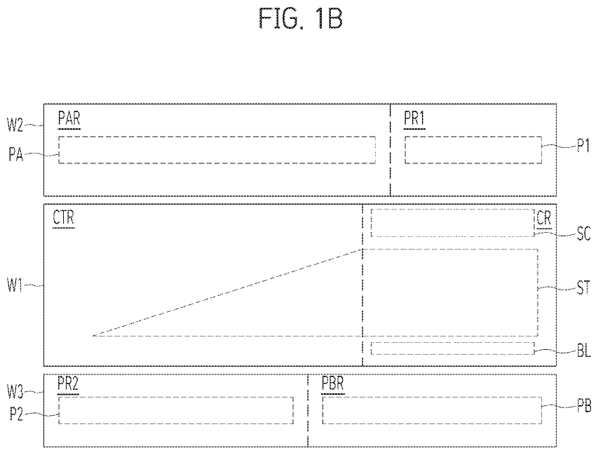

FIGS. 1A and 1B are diagrams for describing a semiconductor device in accordance with one embodiment.

Referring to FIGS. 1A and 1B, the semiconductor device may include a first wafer W1, a second wafer W2, or a third wafer W3, or a combination thereof. The wafers W1 to W3 may each refer to a structure including a substrate or including no substrate. For example, the wafers W1 to W3 may each refer to a structure including no substrate and including various components, for example, channel structures, an interconnection structure, a peripheral circuit, and the like.

The first wafer W1 may include a cell region CR and a contact region CTR. The cell region CR may be a region where stacked memory cells are located. For example, a cell array including memory strings may be located in the cell region CR. The contact region CTR may be a region where an interconnection structure is located. The interconnection structure may provide a path through which a bias for driving the stacked memory cells is transmitted. For example, the interconnection structure may include contact plugs, contact vias, wire lines, or the like.

A source structure SC, a bit line BL, or a stack ST may be located in the cell region CR. The stack ST may be located in the cell region CR, and may extend to the contact region CTR. The stack ST may or may not include a step structure. The step structure of the stack ST may be located in the contact region CTR. The stack ST may include stacked conductive layers. For example, the stack ST may include gate lines. The gate line may be a word line, a source select line, and a drain select line. The gate line may be a local line connected to a global line through pass transistors PA of the second wafer W2. The source structure SC may be located above or below the stack ST. The bit line BL may be located above or below the stack ST. For example, the source structure SC may be located below the stack ST, and the bit line BL may be located above the stack ST. In another example, the source structure SC may be located above the stack ST, and the bit line BL may be located below the stack ST.

An interconnection structure for electrical connection to the stack ST or the memory cells of the cell region CR may be located in the contact region CTR. For example, the step structure or an inverted step structure of the stack ST may be located in the contact region CTR. Contact plugs for electrical connection to the conductive layers of the stack ST may be located in the contact region CTR. For example, when the stack ST has a step structure, conductive layers exposed through the step structure may be electrically connected to the contact plugs, respectively. When the stack ST has no step structure, the contact plugs may extend through the stack ST and be electrically connected to the conductive layers, respectively. Alternatively, the conductive layers may be bent so that upper surfaces of the conductive layers are exposed, so that the conductive layers may be electrically connected to the contact plugs, respectively. In this case, heights of the contact plugs may be substantially the same. The memory cells may receive voltages through the contact plugs and the conductive layers.

The second wafer W2 may include a first peripheral circuit region PR1 and a pass transistor region PAR. The first peripheral circuit region PR1 may include a first peripheral circuit P1, and the pass transistor region PAR may include a row decoder. The row decoder may include a pass transistor PA. The first peripheral circuit P1 may include a voltage generator that supplies a voltage to the stack. The voltage generator may adjust a voltage supplied from the outside and generate an operating voltage to be supplied to the global line. The pass transistor PA may control a connection between the global line and the local line. For example, a bias of the global line may be transmitted to the local line by turning on the pass transistor PA.

The third wafer W3 may include a second peripheral circuit region PR2 and a page buffer region PBR. The second peripheral circuit region PR2 may include a second peripheral circuit P2, and the page buffer region PBR may include a page buffer PB. The page buffer PB may be connected to the bit line BL, and a read operation or program operation of a memory cell may be performed using the page buffer PB. For example, data sensed from a selected memory cell may be temporarily stored in a latch of the page buffer PB, or a voltage or current of the bit line BL may be sensed using the page buffer PB after the start of a read operation or a verify operation. The second peripheral circuit P2 may include a data input/output circuit or a logic circuit that controls the page buffer PB.

Referring to FIG. 1A, the second wafer W2 may be located below the first wafer W1, and the third wafer W3 may be located above the first wafer W1. The first wafer W1 and the second wafer W2 may be bonded to each other, and the first wafer W1 and the third wafer W3 may be bonded to each other. For example, the first wafer W1 may be inverted so that the top of the first wafer W1 and the top of the second wafer W2 may be bonded to each other. The stack ST may include an inverted step structure. The third wafer W3 may be inverted so that the bottom of the first wafer W1 and the top of the third wafer W3 may be bonded to each other. Accordingly, the first wafer W1, the second wafer W2, and the third wafer W3 may be electrically connected to one another.

The cell region CR may be located to face the first peripheral circuit region PR1 and the contact region CTR may be located to face the pass transistor region PAR. In other words, the source structure SC may be located to face the first peripheral circuit P1, and the inverted step structure or contact plugs may be located to face the pass transistor region PAR. Also, the cell region CR may be located to face the page buffer region PBR, and the contact region CTR may be located to face the second peripheral circuit region PR2. In other words, the bit line BL may be located to face the page buffer region PBR, and the inverted step structure or the contact plugs may be located to face the second peripheral circuit P2.

The bit line BL in the cell region CR of the first wafer W1 may be located adjacent to the page buffer region PBR of the third wafer W3, and the contact plugs of the contact region CTR of the first wafer W1 may be located adjacent to the pass transistor region PAR of the second wafer W2. Accordingly, the page buffer PB may receive and sense the voltage or current of the bit line BL of the cell region CR at the shortest distance, and the pass transistor PA may adjust whether the voltage is supplied and then transmit the voltage to the contact plugs of the contact region CTR at the shortest distance.

Referring to FIG. 1B, the third wafer W3 may be located below the first wafer W1, and the second wafer W2 may be located above the first wafer W1. The first wafer W1 and the third wafer W3 may be bonded to each other, and the first wafer W1 and the second wafer W2 may be bonded to each other. For example, the bottom of the first wafer W1 and the top of the third wafer W3 may be bonded to each other. The second wafer W2 may be inverted so that the top of the first wafer W1 and the top of the second wafer W2 may be bonded to each other.

The cell region CR may be located to face the first peripheral circuit region PR1 and the contact region CTR may be located to face the pass transistor region PAR. Also, the cell region CR may be located to face the page buffer region PBR, and the contact region CTR may be located to face the second peripheral circuit region PR2. Accordingly, the bit line BL may be located adjacent to the page buffer region PBR, and the contact plugs may be located adjacent to the pass transistor region PAR.

However, the present disclosure is not limited to bonding the first wafer W1, the second wafer W2, and the third wafer W3 as described above. For example, the first peripheral circuit P1 and the pass transistor PA of the second wafer W2 may be put into the first wafer W1, and the first wafer W1 and the third wafer W3 may be bonded to each other.

According to the structure(s) described above, the first wafer W1 may be formed centered on the memory cell array, and the second wafer W2 and the third wafer W3 may each be formed centered on circuits related to the operation of the memory cell array of the first wafer W1. Accordingly, by configuring circuits related to the operation of the memory cell array to be included in the separate wafers W2 and W3, more memory cells may be placed on the first wafer W1 and more data may be stored.

The first wafer W1 and the second wafer W2 may be bonded to each other so that the inverted step structure or contact plugs of the contact region CTR and the pass transistor PA are adjacent to each other, and the first wafer W1 and the third wafer W3 may be bonded to each other so that the bit line BL of the cell region CR and the page buffer PB are adjacent to each other. Accordingly, the page buffer PB and the bit line BL may be disposed adjacent to each other, and a program operation and a read operation may be improved. The pass transistor PA and the contact plugs 150 may be disposed adjacent to each other, and the length of a bias transmission (electrical) path may be reduced.

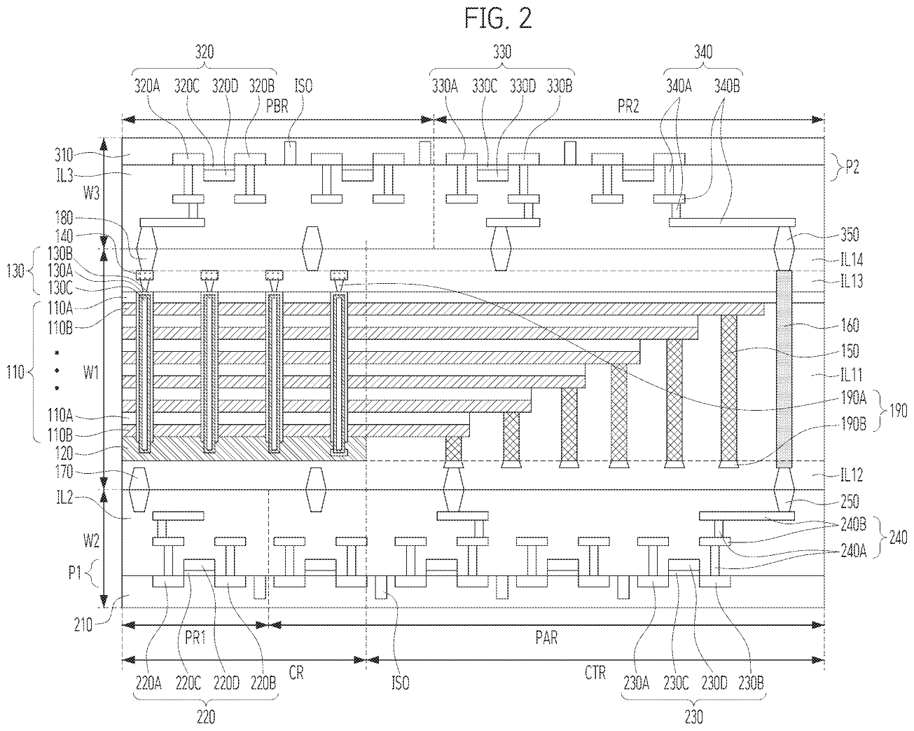

FIG. 2 is a diagram for describing a semiconductor device in accordance with another embodiment. Hereinafter, the content overlapping with the previously described content will be omitted.

Referring to FIG. 2, the semiconductor device may include a first wafer W1, a second wafer W2, or a third wafer W3, or a combination thereof.

The first wafer W1 may include a cell region CR and a contact region CTR, and include a stack 110, a source structure 120, and a bit line 140. The first wafer W1 may further include channel structures 130, first contact plugs 150, a second contact plug 160, first bonding pads 170, second bonding pads 180, or a first interconnection structure 190, or a combination thereof. The first wafer W1 may refer to a structure including a substrate or including no substrate. For example, the first wafer W1 may refer to a first semiconductor structure including the stack 110, the source structure 120, the bit line 140, the channel structures 130, the first contact plugs 150, the second contact plug 160, the first bonding pads 170, the second bonding pads 180, or the first interconnection structure 190, or a combination thereof.

The stack 110 may be located in the cell region CR. The stack 110 may extend to the contact region CTR. The stack 110 may include an inverted step structure. The stack 110 may include insulating layers 110A and conductive layers 110B that are alternately stacked. The conductive layers 110B may be respectively exposed through the inverted step structure. The conductive layers 110B may be local lines such as for example word lines, source select lines, or drain select lines. The insulating layers 110A may each include an insulating material such as for example an oxide, and the conductive layers 110B may each include a conductive material such as for example tungsten or molybdenum.

The source structure 120 may be located in the cell region CR. The source structure 120 may be located below the stack 110. The source structure 120 may be located adjacent to the second wafer W2 and may be spaced apart from the third wafer W3.

The channel structures 130 may be located in the cell region CR. The channel structures 130 may each include a channel layer 130A, a memory layer 130B surrounding the channel layer 130A, or an insulating core 130C in the channel layer 130A, or a combination thereof. The channel structures 130 may extend through the stack 110. For example, the channel structures 130 may extend through the stack 110 and be connected to the source structure 120. The channel layer 130A may be directly connected to the source structure 120 or may be connected to the source structure 120 through an epitaxial pattern.

For reference, the stack 110 of the first wafer W1 may include a first stack and a second stack on the first stack. The channel structures 130 may be located in the first stack and the second stack, respectively, and the channel structures 130 of the first stack and the channel structures 130 of the second stack may be connected to each other.

The bit line 140 may be located in the cell region CR. The bit line 140 may be located on the stack 110. The bit line 140 may be located adjacent to the third wafer W3 and may be spaced apart from the second wafer W2. The channel structures 130 may be located between the bit line 140 and the source structure 120.

The first contact plugs 150 may be located in the contact region CTR. The first contact plugs 150 may be spaced apart from the third wafer W3 and may be located adjacent to the second wafer W2. For example, the first contact plugs 150 may be located adjacent to the second wafer W2 compared to the bit line 140. The first contact plugs 150 may be connected to the conductive layers 110B, respectively. The conductive layers 110B and the second wafer W2 may be electrically connected to each other through the first contact plugs 150. For example, the first contact plugs 150 may be electrically connected to pass transistors 230 of the second wafer W2, respectively. The first contact plugs 150 may be located in an interlayer dielectric layer IL11. The first contact plugs 150 may each include a conductive material such as for example tungsten.

The second contact plug 160 may be located in the contact region CTR. The second contact plug 160 may extend through the first wafer W1 to electrically connect the second wafer W2 and the third wafer W3. For example, the second contact plug 160 may electrically connect the second wafer W2 and the third wafer W3 through the first bonding pad 170, the second bonding pad 180, a third bonding pad 250, and a fourth bonding pad 350. The second contact plug 160 may include a conductive material such as for example tungsten.

The first bonding pad 170 may be located below the stack 110. For example, the first bonding pad 170 may be located below the source structure 120. The first bonding pad 170 may be located in an interlayer dielectric layer IL12. The first bonding pad 170 may connect the first wafer W1 and the second wafer W2. For example, the top of the first wafer W1 and the top of the second wafer W2 may be bonded to each other through one or more bonding pads such as the first bonding pad 170. The first bonding pad 170 may be electrically connected to the first contact plugs 150. For example, the first bonding pad 170 may electrically connect the first contact plugs 150 and the pass transistor 230 of the second wafer W2.

The second bonding pad 180 may be located above the stack 110. For example, the second bonding pad 180 may be located above the bit line 140. The second bonding pad 180 may connect the first wafer W1 and the third wafer W3. For example, the bottom of the first wafer W1 and the top of the third wafer W3 may be bonded to each other through the second bonding pad 180. The second bonding pad 180 may be located on the bit line 140 and electrically connected to the bit line 140. For example, the second bonding pad 180 may electrically connect the bit line 140 and the page buffer of the third wafer W3. The second bonding pad 180 may be located in an interlayer dielectric layer IL14. The second contact plug 160 may extend through the interlayer dielectric layers IL11 to IL14 to electrically connect the first bonding pad 170 and the second bonding pad 180.

The first interconnection structure 190 may include first connection plugs 190A or first wire lines 190B, or a combination thereof. The first connection plugs 190A may connect the bit line 140 and the channel structures 130. The first connection plugs 190A may be located in the interlayer dielectric layer IL13. At least one of the first wire lines 190B may connect at least one of the first contact plugs 150 and at least one of the first bonding pads 170. The first wire lines 190B may be located in the interlayer dielectric layer IL12.

The second wafer W2 may include a first peripheral circuit region PR1 and a pass transistor region PAR. The second wafer W2 may include a first peripheral circuit P1, the pass transistors 230, the third bonding pads 250, a second interconnection structure 240, a substrate 210, or an isolation insulating layer ISO, or a combination thereof. The second wafer W2 may refer to a structure including a substrate or including no substrate. For example, the second wafer W2 may refer to a second semiconductor structure including the first peripheral circuit P1, the pass transistors 230, the third bonding pads 250, the second interconnection structure 240, the substrate 210, or the isolation insulating layer ISO, or a combination thereof.

The first peripheral circuit P1 may be located in the first peripheral circuit region PR1. The first peripheral circuit P1 may be located to face the source structure 120 of the first wafer W1. The first peripheral circuit P1 may include a transistor, a capacitor, a resistor, a voltage generator, and the like. The voltage generator may generate an operating voltage to be supplied to the conductive layers 110B. For example, the voltage generator may generate an operating voltage to be supplied to a global line. The voltage generator may include a transistor 220. The transistor 220 may include junctions 220A and 220B, a gate insulating layer 220C, and a gate electrode 220D. The isolation insulating layer ISO may be located in the substrate 210, and an active region of the transistor 220 may be defined by the isolation insulating layer ISO.

The pass transistors 230 may be located in the pass transistor region PAR. The pass transistors 230 may be located to face the inverted step structure of the stack 110. The pass transistors 230 may be electrically connected to the conductive layers 110B. For example, the conductive layers 110B and the pass transistors 230 may be electrically connected to each other through the first contact plugs 150. Each of the pass transistors 230 may be a high voltage transistor. The pass transistors 230 may control a connection between the global line and a local line. For example, a bias of the global line may be transmitted to the local line by turning on the pass transistors 230. Each of the pass transistors 230 may include a first junction 230A, a second junction 230B, a gate insulating layer 230C, and a gate electrode 230D. The first junction 230A and the second junction 230B may be located in the substrate 210 on both sides of the gate electrode 230D. The gate insulating layer 230C may be located between the gate electrode 230D and the substrate 210.

The third bonding pads 250 may be located above the substrate 210. The third bonding pad 250 may connect the first wafer W1 and the second wafer W2. The third bonding pad 250 may be connected to the first bonding pad 170. For example, the third bonding pad 250 may bond the top of the first wafer W1 and the top of the second wafer W2. The third bonding pads 250 may be located on the pass transistors 230 and electrically connected to the pass transistors 230. For example, the third bonding pads 250 may electrically connect the pass transistors 230 and the conductive layers 110B of the first wafer W1. Voltages supplied from the pass transistors 230 may be supplied to the conductive layers 110B through the third bonding pad 250, the first bonding pad 170, and the first contact plug 150. The third bonding pad 250 may be located in the interlayer dielectric layer IL2.

The second interconnection structure 240 may include second connection plugs 240A or second wire lines 240B, or a combination thereof. At least one of the second connection plugs 240A may be electrically connected to at least one of the pass transistors 230. The second wire lines 240B may connect the second connection plugs 240A to each other, or electrically connect the second connection plug 240A and the third bonding pad 250. Accordingly, the third bonding pad 250 and the pass transistors 230 may be electrically connected to each other by the second interconnection structure 240. The second interconnection structure 240 may be located in the interlayer dielectric layer IL2.

The third wafer W3 may include a second peripheral circuit region PR2 and a page buffer region PBR. The third wafer W3 may include a second peripheral circuit P2, a page buffer, a substrate 310, and an isolation insulating layer ISO, or a combination thereof. The third wafer W3 may further include a third interconnection structure 340 or the fourth bonding pad 350, or a combination thereof. The third wafer W3 may refer to a structure including a substrate or including no substrate. For example, the third wafer W3 may refer to a third semiconductor structure including the second peripheral circuit P2, the page buffer, the substrate 310, and the isolation insulating layer ISO, or a combination thereof.

The page buffer may be located in the page buffer region PBR. The page buffer may be located to face the bit line 140. A transistor 320 may be included in the page buffer. The transistor 320 may include junctions 320A and 320B, a gate insulating layer 320C, and a gate electrode 320D. The page buffer may be connected to the bit line 140, and a read operation or a program operation of a memory cell may be performed using the page buffer. For example, data sensed from a selected memory cell may be temporarily stored in a latch of the page buffer, or a voltage or current of the bit line 140 may be sensed using the page buffer after the start of a read operation or a verify operation.

The second peripheral circuit P2 may be located in the second peripheral circuit region PR2. The second peripheral circuit P2 may be located to face the inverted step structure of the stack 110. The second peripheral circuit P2 may include a data input/output circuit or a logic circuit that controls the page buffer. The second peripheral circuit P2 may include a transistor 330. The transistor 330 may include junctions 330A and 330B, a gate insulating layer 330C, and a gate electrode 330D.

The fourth bonding pads 350 may be located below the substrate 310. The fourth bonding pads 350 may be located on the transistors 320 and 330, and electrically connected to the transistors 320 and 330, respectively. The fourth bonding pad 350 may be connected to the second bonding pad 180. For example, the fourth bonding pad 350 may bond the bottom of the first wafer W1 and the top of the third wafer W3. The fourth bonding pad 350 may be electrically connected to the page buffer. For example, the fourth bonding pad 350 may electrically connect the page buffer and the bit line 140 of the first wafer W1. The page buffer may receive and sense the voltage of the bit line 140 through the second bonding pad 180 and the fourth bonding pad 350. The fourth bonding pad 350 may be located in the interlayer dielectric layer IL3. The fourth bonding pad 350 may connect the first wafer W1 and the third wafer W3.

The third interconnection structure 340 may include third connection plugs 340A or third wire lines 340B, or a combination thereof. At least one of the third connection plugs 340A may be electrically connected to at least one of the transistors 320 and 330. The third wire lines 340B may connect the third connection plugs 340A to each other, or electrically connect the third connection plugs 340A and the fourth bonding pad 350. Accordingly, the fourth bonding pad 350 and the transistors 320 and 330 may be electrically connected to each other by the third interconnection structure 340. The third interconnection structure 340 may be located in the interlayer dielectric layer IL3.

According to the structure(s) described above, the bit line 140 and the first contact plugs 150 of the first wafer W1 may be formed at positions diagonally across from each other. For example, the bit line 140 may be located adjacent to the third wafer W3, and the first contact plugs 150 may be located adjacent to the second wafer W2. Accordingly, by efficiently disposing the bit line 140 and the first contact plugs 150, a process of forming the interconnection structures 190, 240, and 340 for connecting the bit line 140 or the first contact plugs 150 may be simplified.

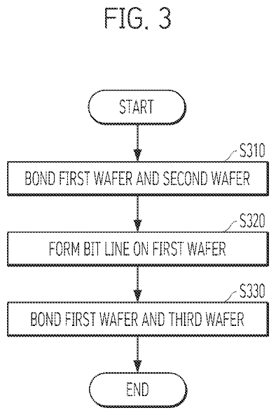

FIG. 3 is a diagram for describing a manufacturing method of a semiconductor device in accordance with another embodiment. Hereinafter, the content overlapping with the previously described content will be omitted.

Referring to FIG. 3, a first wafer and a second wafer may be bonded to each other (S310). The first wafer and the second wafer may each refer to a structure including a substrate or including no substrate. For example, the first wafer may refer to a first semiconductor structure including a stack including a step structure, a source structure located above the stack, and channel structures extending through the stack. The second wafer may refer to a second semiconductor structure including pass transistors and a first peripheral circuit. An upper surface of the first wafer and an upper surface of the second wafer may be bonded to each other. A lower surface of the first wafer and the upper surface of the second wafer may also be bonded to each other. The first peripheral circuit may include a voltage generator that transmits a voltage to conductive layers of the stack.

Subsequently, a bit line may be formed on the first wafer (S320). For example, when the upper surface of the first wafer and the upper surface of the second wafer are bonded to each other, the bit line may be formed on the lower surface of the first wafer.

Subsequently, the first wafer and a third wafer may be bonded to each other (S330). The third wafer may refer to a structure including a substrate or including no substrate. For example, the third wafer may refer to a third semiconductor structure including a page buffer and a second peripheral circuit. The lower surface of the first wafer and an upper surface of the third wafer may be bonded to each other. The second peripheral circuit may include a data input/output circuit or a logic circuit that controls the page buffer.

According to the manufacturing method described above, by forming wafers W1 to W3 each including different structures and bonding the wafers W1 to W3 to one another, the structures may be efficiently disposed.

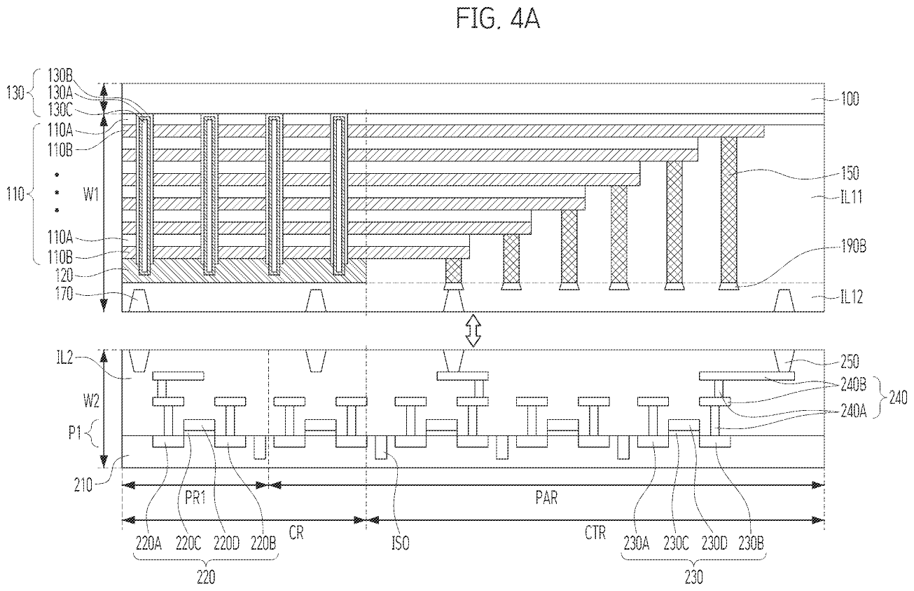

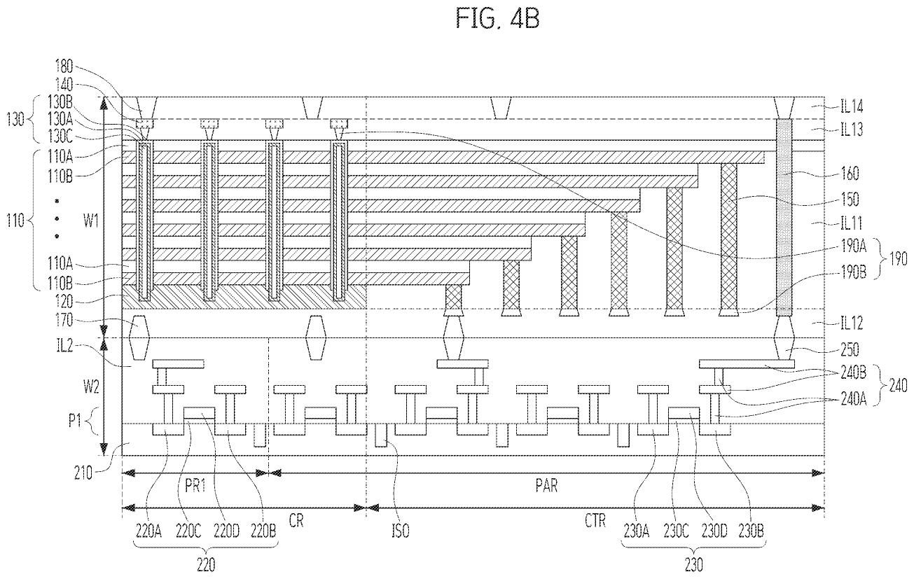

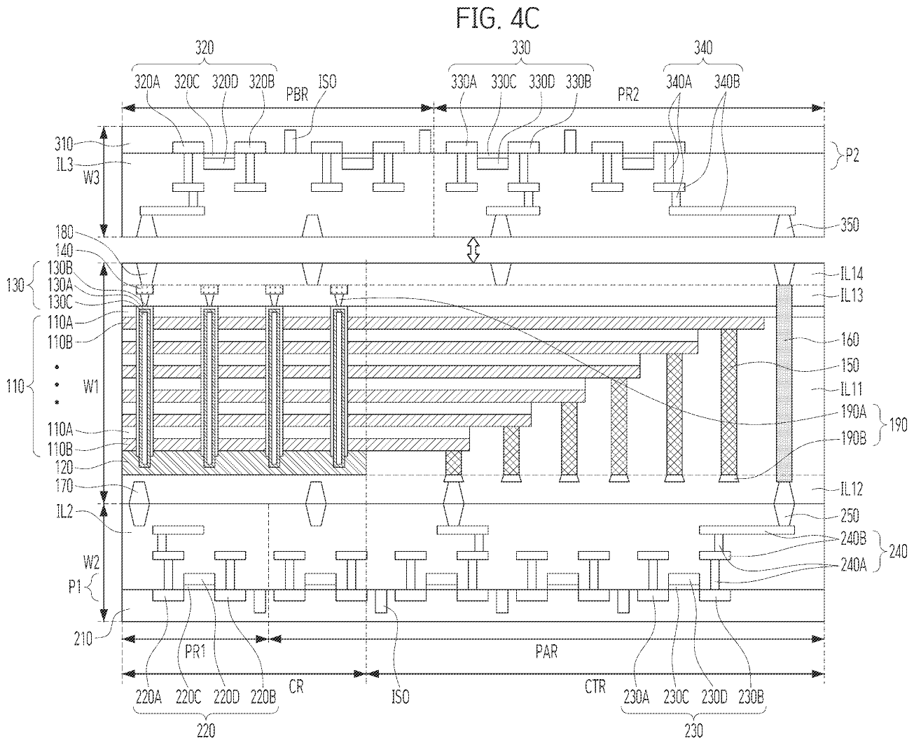

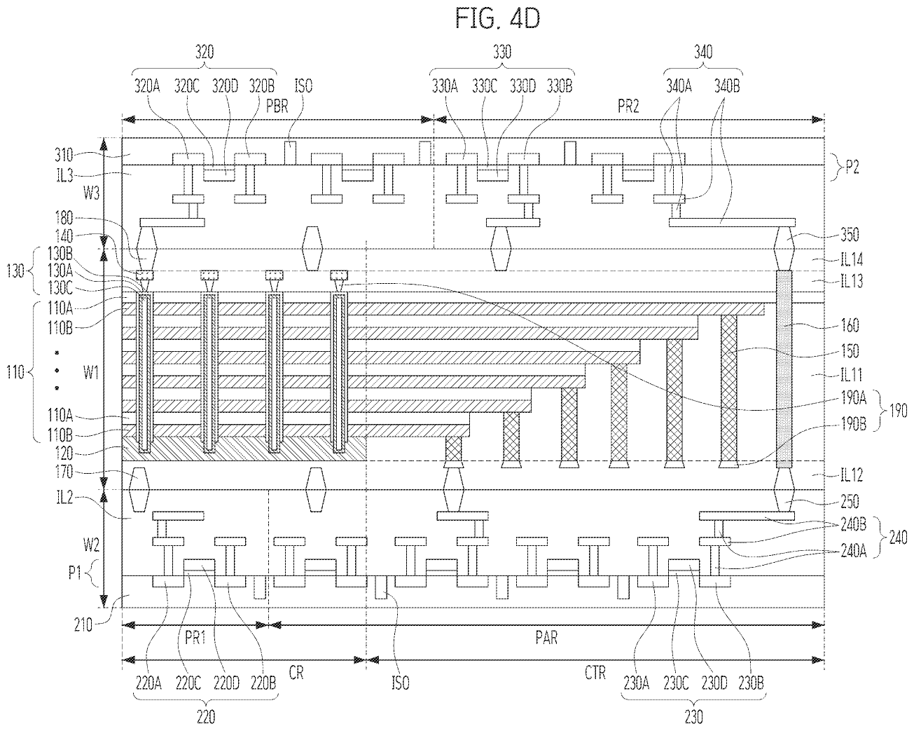

FIGS. 4A to 4D are diagrams for describing a manufacturing method of a semiconductor device in accordance with other embodiments. Hereinafter, the content overlapping with the previously described content will be omitted.

Referring to FIG. 4A, a first wafer W1 may be formed. The first wafer W1 may include a cell region CR and a contact region CTR. First, a preliminary stack may be formed by alternately stacking insulating layers 110A and sacrificial layers on a substrate 100. The insulating layers 110A may each include an insulating material such as for example an oxide, and the sacrificial layers may each include a sacrificial material such as for example a nitride. The preliminary stack may include a step structure. Channel structures 130 extending through the preliminary stack may be formed. Each of the channel structures 130 may include a channel layer 130A, a memory layer 130B surrounding the channel layer 130A, or an insulating core 130C in the channel layer 130A, or a combination thereof. Subsequently, slits extending through the preliminary stack may be formed, and the sacrificial layers may be replaced with conductive layers 110B through the slits. Thus, a stack 110 including the insulating layers 110A and the conductive layers 110B that are alternately stacked may be defined. The stack 110 may be formed in the cell region CR and may extend to the contact region CTR. The stack 110 may include a step structure. The conductive layers 110B may be exposed through the step structure of the stack 110. The conductive layers 110B may be word lines, source select lines, or drain select lines.

However, the present disclosure is not limited thereto, and the stack 110 may also be formed by alternately stacking the insulating layers 110A and the conductive layers 110B from the beginning. The conductive layers 110B may be silicidated through the slits.

A source structure 120 located above the stack 110 may be formed. The source structure 120 may be formed in the cell region CR. The source structure 120 may be electrically connected to the channel structures 130. For example, the source structure 120 may be directly connected to the channel layer 130A, or may be connected to the channel layer 130A through an epitaxial pattern.

First contact plugs 150 respectively connected to the conductive layers 110B may be formed. The first contact plugs 150 may be formed in the contact region CTR. The first contact plugs 150 may extend through an interlayer dielectric layer IL11, and may be electrically connected to the conductive layers 110B, respectively. However, the present disclosure is not limited thereto, and when the stack 110 has no step structure, the first contact plugs 150 may extend through the stack 110 and may be electrically connected to the conductive layers 110B, respectively.

Subsequently, wire lines 190B may be formed on the first contact plugs 150. The wire lines 190B may be electrically connected to the first contact plugs 150. An interlayer dielectric layer IL12 may be formed on the interlayer dielectric layer IL11. The wire lines 190B may be formed in the interlayer dielectric layer IL12.

First bonding pads 170 may be formed on the source structure 120. However, the present disclosure is not limited thereto, and the first bonding pads 170 may be formed in the cell region CR and the contact region CTR. The first bonding pads 170 may be formed in the interlayer dielectric layer IL12. The first bonding pads 170 may be electrically connected to the first contact plugs 150. For example, at least one of the first bonding pads 170 may be electrically connected to the first contact plug 150 through the wire line 190B.

A second wafer W2 may be formed. The second wafer W2 may include a first peripheral circuit region PR1 and a pass transistor region PAR. A first peripheral circuit P1 may be formed in the first peripheral circuit region PR1. The first peripheral circuit P1 may be formed on a substrate 210 and may be formed to face the source structure 120. The first peripheral circuit P1 may include a transistor, a capacitor, a resistor, a voltage generator, and the like. The voltage generator may adjust a voltage supplied from the outside and generate an operating voltage to be supplied to a global line. The voltage generator may include a transistor 220. The transistor 220 may include junctions 220A and 220B, a gate insulating layer 220C, and a gate electrode 220D. An isolation insulating layer ISO may be formed in the substrate 210, and an active region of the transistor 220 may be defined by the isolation insulating layer ISO.

Pass transistors 230 may be formed in the pass transistor region PAR. The pass transistors 230 may be formed to face an inverted step structure of the stack 110. The pass transistors 230 may control a connection between the global line and a local line connecting to one of the first contact plugs 150 of the step structure. For example, a bias of the global line may be transmitted to the local line by turning on the pass transistors 230. Each of the pass transistors 230 may include junctions 230A and 230B, a gate insulating layer 230C, and a gate electrode 230D. The junctions 230A and 230B may be formed in the substrate 210 on both sides of the gate electrode 230D. Each of the pass transistors 230 may be a high voltage transistor.

Subsequently, third bonding pads 250 may be formed on the pass transistors 230. First, a second interconnection structure 240 may be formed on the pass transistors 230. The second interconnection structure 240 may include a second connection plug 240A or a second wire line 240B. Subsequently, the third bonding pads 250 may be formed on the second interconnection structure 240. The second interconnection structure 240 and the third bonding pads 250 may be formed in the interlayer dielectric layer IL2. The third bonding pads 250 may be electrically connected to the pass transistors 230, respectively. For example, at least one of the third bonding pads 250 may be electrically connected to the pass transistor 230 by the second interconnection structure 240.

Subsequently, the first wafer W1 and the second wafer W2 may be bonded to each other. For example, an upper surface of the first wafer W1 and an upper surface of the second wafer W2 may be bonded to each other. The first bonding pads 170 of the first wafer W1 and the third bonding pads 250 of the second wafer W2 may be bonded to each other. Since the first wafer W1 is rotated and bonded to the second wafer W2, the first wafer W1 may include the stack 110 having an inverted step structure.

The first wafer W1 and the second wafer W2 may be bonded to each other so that the pass transistors 230 face the step structure of the stack 110 and the first peripheral circuit P1 faces the source structure 120. In other words, the first wafer W1 and the second wafer W2 may be bonded to each other so that the first contact plugs 150 electrically connected to the conductive layers 110B of the stack 110 face the pass transistors 230. Accordingly, the pass transistors 230 may be electrically connected to the conductive layers 110B through the first contact plugs 150, respectively.

Referring to FIG. 4B, a bit line 140 may be formed. The first wafer W1 and the second wafer W2 may be bonded to each other, and the bit line 140 may be formed on the first wafer W1. The bit line 140 may be formed in the cell region CR. Accordingly, the bit line 140 may be formed on the lower surface of the cell region CR of the first wafer W1. The bit line 140 may be formed on the stack 110 including the inverted step structure. For example, the substrate 100 may be removed and the bit line 140 may be formed on the stack 110. The bit line 140 may be formed on an interlayer dielectric layer IL13.

A second contact plug 160 may be formed. The second contact plug 160 may be formed in the contact region CTR. The second contact plug 160 may extend through the first wafer W1 and be electrically connected to the first bonding pad 170.

Subsequently, second bonding pads 180 may be formed on the bit line 140. The second bonding pads 180 may be formed on an interlayer dielectric layer IL14. The second bonding pad 180 may be located on the bit line 140 and electrically connected to the bit line 140. At least one of the second bonding pads 180 may be electrically connected to the second contact plug 160. For example, the second bonding pad 180 and the first bonding pad 170 may be electrically connected to each other through the second contact plug 160.

Referring to FIGS. 4C and 4D, a third wafer W3 may be formed. The third wafer W3 may include a second peripheral circuit region PR2 and a page buffer region PBR. A second peripheral circuit P2 may be formed in the second peripheral circuit region PR2. The second peripheral circuit P2 may be formed on a substrate 310 and may be formed to face the inverted step structure of the stack 110 of the first wafer W1. The second peripheral circuit P2 may include a data input/output circuit or a logic circuit that controls a page buffer. The second peripheral circuit P2 may include a transistor 330. The transistor 330 may include junctions 330A and 330B, a gate insulating layer 330C, and a gate electrode 330D. An isolation insulating layer ISO may be formed in the substrate 310, and an active region of the transistor 330 may be defined by the isolation insulating layer ISO.

The page buffer may be formed in the page buffer region PBR. The page buffer may be formed to face the bit line 140. The page buffer may temporarily store data sensed from a selected memory cell in a latch of the page buffer, or a voltage or current of the bit line 140 may be sensed using the page buffer after the start of a read operation or a verify operation. A transistor 320 may be included in the page buffer. The transistor 320 may include junctions 320A and 320B, a gate insulating layer 320C, and a gate electrode 320D.

Subsequently, fourth bonding pads 350 may be formed on the page buffer. First, a third interconnection structure 340 may be formed on the page buffer. The third interconnection structure 340 may include a third connection plug 340A or a third wire line 340B. Subsequently, the fourth bonding pads 350 may be formed on the third interconnection structure 340. The third interconnection structure 340 may be formed in the interlayer dielectric layer IL3. The fourth bonding pads 350 may be electrically connected to the page buffer. For example, at least one of the fourth bonding pads 350 may be connected to the page buffer by the third interconnection structure 340. Subsequently, the first wafer W1 and the third wafer W3 may be bonded to each other. For example, the lower surface of the first wafer W1 and an upper surface of the third wafer W3 may be bonded to each other. The second bonding pads 180 of the first wafer W1 and the fourth bonding pads 350 of the third wafer W3 may be bonded to each other. The first wafer W1 and the third wafer W3 may be bonded to each other so that the page buffer faces the bit line 140 and the second peripheral circuit P2 faces the inverted step structure. Accordingly, the page buffer may receive and sense a voltage from the bit line 140 at the shortest distance.

The third wafer W3 may be electrically connected to the second wafer W2. For example, the second contact plug 160 may extend through the first wafer W1 to electrically connect the second wafer W2 and the third wafer W3. In other words, the second contact plug 160 may electrically connect the second wafer W2 and the third wafer W3 through the first bonding pad 170, the second bonding pad 180, the third bonding pad 250, and the fourth bonding pad 350.

According to the process described above, the stack 110 constituting the memory cell array, the channel structure 130, the first contact plug 150, and the like may be formed on the first wafer W1, and the second wafer W2 and the third wafer W3 may form the peripheral circuits P1 and P2, the pass transistors 230, the page buffer, and the like related to the operation of the memory cell array of the first wafer W1. Accordingly, by forming circuits related to the operation of the memory cell array on the separate wafers W2 and W3, more memory cells may be formed on the first wafer W1, and thus more data may be stored.

The bit line 140 may be formed below the cell region CR of the first wafer W1 and located to face the page buffer of the third wafer W3. The first contact plugs 150 may be formed in the contact region CTR of the first wafer W1 and located to face the pass transistors 230. The bit line 140 and the first contact plugs 150 may be formed at positions diagonally across from each other. Accordingly, the page buffer and the bit line 140 may be arranged adjacent to each other, and a program operation and a read operation may be improved. The pass transistors 230 and the first contact plugs 150 may be disposed adjacent to each other, and the length of a bias transmission (electrical) path may be reduced.

Although embodiments according to the technical idea of the present disclosure have been described above with reference to the accompanying drawings, this is only for explaining the embodiments according to the present disclosure, and the present disclosure is not limited to the above embodiments. Various types of substitutions, modifications, and changes for the embodiments may be made by those skilled in the art, to which the present disclosure pertains, without departing from the present disclosure, and it should be construed that these substitutions, modifications, and changes belong to the scope of the present disclosure.

What is claimed is:

1. A semiconductor device comprising:
a first semiconductor structure including a stack including an inverted step structure, a source structure located below the stack, a bit line located above the stack, and channel structures extending through the stack;
a second semiconductor structure bonded to the first semiconductor structure, and the second semiconductor structure including a) pass transistors located to face the inverted step structure and b) a first peripheral circuit located to face the source structure; and
a third semiconductor structure bonded to the first semiconductor structure, and the third semiconductor structure including a) a page buffer located to face the bit line and b) a second peripheral circuit located to face the inverted step structure.

2. The semiconductor device of claim 1, wherein the stack includes conductive layers respectively exposed through the inverted step structure.

3. The semiconductor device of claim 2, further comprising:
first contact plugs connected to the conductive layers, respectively.

4. The semiconductor device of claim 3, wherein the conductive layers and the pass transistors are electrically connected to each other through the first contact plugs.

5. The semiconductor device of claim 2, wherein the first peripheral circuit includes a voltage generator that transmits a voltage to the conductive layers.

6. The semiconductor device of claim 1, wherein the second peripheral circuit includes a data input/output circuit or a logic circuit that controls the page buffer.

7. The semiconductor device of claim 1, further comprising:
a second contact plug that extends through the first semiconductor structure and electrically connects the second semiconductor structure and the third semiconductor structure.

8. The semiconductor device of claim 1, wherein the first semiconductor structure includes a first bonding pad located below the source structure and a second bonding pad located above the bit line.

9. The semiconductor device of claim 8, wherein the second semiconductor structure includes a third bonding pad bonded to the first bonding pad.

10. The semiconductor device of claim 8, wherein the third semiconductor structure includes a fourth bonding pad bonded to the second bonding pad.

11. The semiconductor device of claim 1, wherein each of the pass transistors is a high voltage transistor.
